(19) United States
(12) Patent Application Publication
(10) Pub. No.: US 2024/0085793 A1
(43) Pub. Date: Mar. 14, 2024

(54) METHOD OF FORMING A MOISTURE BARRIER ON PHOTOSENSITIVE ORGANOMETALLIC OXIDES

(71) Applicant: Tokyo Electron Limited, Tokyo (JP)

(72) Inventors: Kandabara Tapily, Albany, NY (US); Nobuo Matsuki, Nirasaki City (JP)

(21) Appl. No.: 18/216,874

(22) Filed: Jun. 30, 2023

Related U.S. Application Data
(60) Provisional application No. 63/404,772, filed on Sep. 8, 2022.

(51) Int. Cl. G03F 7/16; G03F 7/00; H01L 21/027

(52) U.S. Cl. CPC G03F 7/167; G03F 7/70033; H01L 21/0273

(57) ABSTRACT

Various embodiments of methods are provided for forming a moisture barrier layer on an EUV-active photoresist film before patterning the EUV-active photoresist film with EUV lithography. According to one embodiment, the methods disclosed herein may form an EUV-active photoresist film on a surface of a semiconductor substrate and a moisture barrier layer containing a hydrocarbon polymer on the EUV-active photoresist film before the EUV-active photoresist film is patterned with EUV lithography to form a patterned photoresist on the substrate surface. In some embodiments, a first hydrocarbon polymer layer may be formed on the substrate surface before an EUV-active photoresist film is formed on the first hydrocarbon polymer layer. By providing a hydrocarbon polymer layer above and/or below the EUV-active photoresist film, the disclosed methods improve the performance of the EUV-active photoresist film by protecting upper/lower surfaces of the EUV-active photoresist film from undergoing unwanted chemical reactions.

This application claims priority to U.S. Provisional Patent Application Ser. No. 63/404,772, filed Sep. 8, 2022, entitled “Method of Forming a Moisture Barrier on Photosensitive Organometallic Oxides,” the disclosure of which is expressly incorporated herein, in its entirety, by reference. This application is related to U.S. patent application Ser. No. 18/216,168, filed Jun. 29, 2023, entitled “Method of Forming Photosensitive Organometallic Oxides by Chemical Vapor Polymerization”; the disclosure of which is expressly incorporated herein, in its entirety, by reference.

### TECHNICAL FIELD

The present invention relates generally to extreme ultraviolet (EUV) lithography, and, in particular embodiments, to EUV-active films and methods of formation thereof.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

A common patterning method is to use a photolithography process to expose a coating of photoresist over the target layer to a pattern of actinic radiation and then transfer the relief pattern to the target layer or an underlying hard mask layer formed over the target layer. With this technique, the minimum feature size would be limited by the resolution of the optical system. Scaling of feature sizes for advanced technology nodes is driving lithography to improve resolution. For sub-10 nm technology nodes (for example, 7 nm and 5 nm technology nodes), 13.5 nm extreme ultraviolet (EUV) lithography is commonly used to pattern a photoresistive film with EUV radiation.

EUV lithography techniques offer significant advantages in patterning sub-10 nm features with its high optical resolution. However, one major engineering challenge for EUV lithography is that photoresists developed for conventional photolithography systems may not satisfy the cost and/or quality requirements for patterning sub-10 nm features. For example, chemically amplified resist (CAR) or similar polymer resists, which are commonly used in 193 nm lithography, are typically produced using liquid based spin-on techniques that consume a significant amount of complex metal cluster precursors, resulting in very high cost. CARs also tend to have low absorption coefficients at 13.5 nm, and thus, may suffer poor sensitivity. Further, the diffusion of photo-activated species in CARs may cause blurring and increase line-edge roughness (LER) in the subsequently formed pattern.

As an alternative to CARs, vapor-deposited metal oxide-containing films have been investigated for use as EUV-active hardmasks in EUV lithography techniques. For example, U.S. Pat. No. 9,996,004, entitled “EUV Photopatterning of Vapor-Deposited Metal Oxide-Containing Hardmasks”, describes various processes for forming metal oxide-containing hardmasks utilized for EUV patterning. In the '004 patent, an EUV-sensitive metal oxide-containing film is vapor deposited on a semiconductor substrate by chemical vapor deposition (CVD) or atomic layer deposition (ALD). During the deposition process, an organotin oxide precursor is reacted with a carbon dioxide-containing plasma at a relatively high deposition temperature (in one example, between 250° C. and 350° C.) to deposit the EUV-sensitive metal oxide-containing film on the semiconductor substrate. After CVD/ALD deposition, the metal oxide-containing film (e.g., a metal oxide resist (MOR) film) is transferred to an EUV patterning tool and patterned via direct EUV exposure (i.e., without the use of a photoresist), followed by pattern development, to form a metal oxide-containing hardmask.

The processes described in the '004 patent suffer from various disadvantages. For example, the deposition processes described in the '004 patent react various organotin oxide precursors with an oxidizer (e.g., carbon dioxide or carbon monoxide) in a typical CVD/ALD process to form a solid metal oxide-containing film on the semiconductor substrate. The oxidizer utilized within the CVD/ALD deposition process increases the density of the metal oxide-containing film and creates weak and unstable bonds (for example, Sn—OH and Sn—O—Sn bonds), which deteriorate EUV photosensitivity of the subsequently formed hardmask.

Innovations on EUV photolithographic techniques are needed to satisfy the cost and quality requirements for patterning at the sub-10 nm node regime. To meet these needs, it may be desirable to develop a new class of photoresists for EUV lithography with better performance.

### SUMMARY

The present disclosure generally relates to photolithographic processes, and more particularly, to improved process flows and methods for protecting an EUV-active photoresist film formed over a semiconductor substrate.

The improved process flows and methods described herein protect an EUV-active photoresist film by providing a hydrocarbon polymer layer above and/or below the EUV-active photoresist film. The hydrocarbon polymer layer formed above the EUV-active photoresist film serves as a barrier layer, which prevents undesirable reactions on an upper surface of the EUV-active photoresist film. In one non-limiting example, the hydrocarbon polymer layer formed above the EUV-active photoresist film may serve as a moisture control/barrier layer, which prevents the EUV-active photoresist film from chemically reacting with moisture in the ambient environment and forming undesirable metal-oxide-metal species on the surface of the photoresist. The hydrocarbon polymer layer formed below the EUV-active photoresist film prevents the EUV-active photoresist film from chemically reacting with the underlying silicon-containing substrate and forming undesirable metal-oxide-silicon species on the substrate surface. As such, the hydrocarbon polymer layers described herein improve performance of an EUV-active photoresist film by preventing unwanted reactions on upper/lower surfaces of the photoresist.

According to one embodiment, a method is provided herein for processing a semiconductor substrate. The method may generally include forming an extreme ultraviolet (EUV)-active photoresist film on a surface of the semiconductor substrate, the EUV-active photoresist film comprising an organometallic oxide; plasma depositing a moisture barrier layer containing a hydrocarbon polymer on the EUV-active photoresist film; and patterning the EUV-active photoresist film with EUV lithography to form a patterned photoresist on the surface of the semiconductor substrate.

According to another embodiment, a method is provided herein for processing a semiconductor substrate. The method may generally include plasma depositing a first hydrocarbon polymer layer on a surface of the semiconductor substrate; plasma depositing an extreme ultraviolet (EUV)-active photoresist film on the first hydrocarbon polymer layer; plasma depositing a second hydrocarbon polymer layer on the EUV-active photoresist film; and patterning the EUV-active photoresist film with EUV lithography to form a patterned photoresist on the surface of the semiconductor substrate.

In various embodiments, the EUV-active photoresist film disclosed herein may be an organometallic oxide or metal oxide resist (MOR). For example, the EUV-active photoresist film may be an organometallic oxide containing tin (Sn), zirconium (Zr), indium (In), antimony (Sb), bismuth (Bi), zinc (Zn), hafnium (Hf), aluminum (Al) or combinations thereof. In some embodiments, the EUV-active photoresist film may be an organometallic oxide with polymerized carbon-carbon bonds.

The first hydrocarbon polymer layer and/or the second hydrocarbon polymer layer (i.e., the moisture barrier layer) may contain a wide variety of hydrocarbon polymers. In some embodiments, the hydrocarbon polymer may include carbon and hydrogen. For example, the hydrocarbon polymer may include: a) carbon, hydrogen, and oxygen, b) carbon, hydrogen, oxygen, and nitrogen, or c) carbon, hydrogen, and nitrogen.

The first hydrocarbon polymer layer and/or the second hydrocarbon polymer layer (i.e., the moisture barrier layer) may be formed by plasma exciting a wide variety of precursors. For example, a hydrocarbon precursor, an aldehyde precursor and/or an amine precursor may be plasma exited to form one or more of the first and second hydrocarbon polymer layers. In some embodiments, the plasma excitation can further include an additive gas, such as for example, hydrogen (H₂), helium (He), argon (Ar), neon (Ne), xenon (Xe), nitrogen (N₂), carbon monoxide (CO), ammonia (NH₃) or hydrogen sulfide (H₂S).

In some embodiments, a hydrocarbon precursor may be used to form the hydrocarbon polymer layer. The hydrocarbon precursor can have the formula C_{α}H_{β}, where α is an integer of 1 or more, and β is an integer of 1 or more. Non-limiting examples of hydrocarbon precursors having the formula C_{α}H_{β} include, but are not limited to, a methyl radical (CH₃), acetylene (C₂H₂), ethylene (C₂H₄), a propyl radical (C₃H₇), and styrene (C₆H₅CH═CH₂).

In other embodiments, an aldehyde precursor may be used to form the hydrocarbon polymer layer. The aldehyde precursor having the formula C_{α}H_{β}O_{γ}, where α is an integer of 1 or more, β is an integer of 1 or more, and γ is an integer of 1 or more. One example of an aldehyde precursor having the formula C_{α}H_{β}O_{γ} includes benzaldehyde (C₆H₅CHO).

In yet other embodiments, an amine precursor may be used to form the hydrocarbon polymer layer, the amine precursor having the formula C_{α}H_{β}N_{γ}O_{δ}, where α is an integer of 1 or more, β is an integer of 1 or more, γ is an integer of 1 or more and δ is an integer of 0 or more. One example of an amine precursor having the formula C_{α}H_{β}N_{γ}O_{δ} includes phenylenediamine (C₆H₄(NH₂)₂).

A wide variety of plasma processing chambers may be utilized to plasma deposit the first hydrocarbon polymer layer and/or the second hydrocarbon polymer layer (i.e., the moisture barrier layer). For example, a capacitively coupled plasma (CCP) processing chamber, inductively coupled plasma (ICP) processing chamber or a plasma processing system with a remote plasma source, such as a radio frequency (RF), very high frequency (VHF), and microwave frequency (MWF) source, may be used. In one example embodiment, the plasma depositing steps used to plasma deposit the first hydrocarbon polymer layer and/or the second hydrocarbon polymer layer (i.e., the moisture barrier layer) may be performed within a CCP processing chamber having a source frequency of 13.56 MHz-60 MHz, a source power between about 10 W and about 500 W, an ion energy of about 50 eV or less, a gas pressure between about 100 mTorr and about 20 Torr, and a substrate temperature less than about 100° C.

In some embodiments, a relatively thin (for example, about 1 nm to 10 nm) moisture barrier layer (or second hydrocarbon polymer layer) may be deposited on the EUV-active photoresist film. In such embodiments, the EUV-active photoresist film may be patterned by: (a) exposing the moisture barrier layer and the EUV-active photoresist film to EUV radiation, wherein reacted regions of the EUV-active photoresist film exposed to the EUV radiation are converted to a reacted photoresist, while regions of the EUV-active photoresist not exposed to the EUV radiation remain unreacted; (b) removing the moisture barrier layer; and (c) removing certain regions of the EUV-active photoresist to form a photoresist pattern.

In some embodiments, the patterning step may remove the unreacted regions of the EUV-active photoresist to form a first photoresist pattern (for example, a negative tone photoresist) on the substrate. In some embodiments, the method may further include selectively depositing a material film on upper surfaces of the first photoresist pattern relative to the exposed surfaces of the semiconductor substrate.

In some embodiments, the patterning step may remove the reacted regions of the EUV-active photoresist to form a second photoresist pattern (for example, a positive tone photoresist) on the substrate. In some embodiments, the method may further include selectively depositing a material film on exposed surfaces of the semiconductor substrate relative to the second photoresist pattern.

In other embodiments, a relatively thick (for example, greater than about 10 nm) moisture barrier layer (or second hydrocarbon polymer layer) may be deposited on the EUV-active photoresist film. In such embodiments, the EUV-active photoresist film may be patterned by: (a) exposing the moisture barrier layer to EUV radiation, wherein first regions of the moisture barrier layer exposed to the EUV radiation are converted to a reacted moisture barrier layer and second regions of the moisture barrier layer not exposed to the EUV radiation remain unreacted; (b) removing the first regions of the of the moisture barrier layer converted to the reacted moisture barrier layer to form a patterned moisture barrier layer; and (c) exposing the EUV-active photoresist film to EUV radiation through openings in the patterned moisture barrier layer, wherein reacted regions of the EUV-active photoresist film exposed to the EUV radiation are converted to a reacted photoresist, and wherein unreacted regions of the EUV-active photoresist not exposed to the EUV radiation remain unreacted. In some embodiments, the method may further include selectively depositing a material film onto upper surfaces of the reacted photoresist and removing the patterned moisture barrier layer. The patterned moisture barrier layer may be removed before or after the material film is selectively deposited onto the upper surfaces of the reacted photoresist.

Various embodiments of methods are provided herein for processing a semiconductor substrate, and more specifically, for forming moisture barrier layer over an EUV-active photoresist film. Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed inventions. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a process flow diagram illustrating an example process flow to form an EUV-active photoresist film on a surface of a semiconductor substrate in accordance with one embodiment of the present disclosure.

FIG. 1B illustrates example chemistry that can be utilized for the chemical vapor polymer deposition and heat treatment steps shown in FIG. 1A, including an example metal precursor that can be used during the plasma process step to form an example non-solid, organometallic oxide polymer layer on the substrate surface, and an example EUV-active photoresist film that can be formed during the subsequently performed heat treatment step.

FIG. 2A is a flowchart diagram illustrating one embodiment of a method for processing a semiconductor substrate in accordance with the present disclosure.

FIG. 2B is a flowchart diagram illustrating another embodiment of a method for processing a semiconductor substrate in accordance with the present disclosure.

FIG. 3 is a process flow diagram illustrating an example process flow that can be used to form a film structure comprising a moisture barrier layer formed over an EUV-active photoresist film in accordance with one embodiment of the present disclosure.

FIG. 4 is a process flow diagram illustrating an example process flow that can be used to form a film structure comprising a first hydrocarbon layer formed under an EUV-active photoresist film and a second hydrocarbon layer formed over the EUV-active photoresist film in accordance with another embodiment of the present disclosure.

FIG. 5 is a process flow diagram illustrating an example process flow that can be used to pattern a film structure containing a moisture barrier layer formed over an EUV-active photoresist film, thus forming a patterned photoresist.

FIGS. 6A-6B are process flow diagrams illustrating example process flows that can be used to perform Area Selective Deposition (ASD) using patterned photoresists in accordance with a first embodiment of the present disclosure.

FIG. 7 is a process flow diagram illustrating an example process flow that can be used to perform Area Selective Deposition (ASD) using a patterned photoresist in accordance with a second embodiment of the present disclosure.

FIG. 8 is a process flow diagram illustrating an example process flow that can be used to perform Area Selective Deposition (ASD) using a patterned photoresist in accordance with a third embodiment of the present disclosure.

### DETAILED DESCRIPTION OF ILLUSTRATIVE EMBODIMENTS

The present disclosure relates to photolithographic processes, more particularly, to improved process flows and methods to form a moisture barrier layer over an EUV-active photoresist film formed on a semiconductor substrate.

The present disclosure provides improved process flows and methods to form an extreme ultraviolet (EUV)-active photoresist on a semiconductor substrate. The EUV-active photoresist film described herein may be an organometallic oxide polymerized with carbon-carbon bonds (e.g., a metal alkoxy polymer film). The presence of the carbon-carbon bonds increases the mechanical strength and photosensitivity of the EUV-active photoresist film compared to conventional photoresists used for EUV lithography.

Many EUV-active photoresist films (including conventional metal oxide resist (MOR) films and metal alkoxy polymer films) are chemically and mechanically fragile. For example, tin(Sn)-containing alkoxy polymer films containing Sn—O—CₙHₘ or Sn—OH surface species easily absorb moisture from the air or from the processing environment. In some cases, the Sn—O—CₙHₘ surface species may react with moisture in the ambient environment and undergo a chemical reaction to form metal-oxide-metal species (for example, Sn—O—Sn species) on exposed surfaces of the EUV-active photoresist film. This can have a detrimental effect on the material properties and quality of the EUV-active photoresist film during photolithography processing. Therefore, protecting an EUV-active photoresist film from moisture in the ambient environment can be highly beneficial.

The present disclosure also provides improved process flows and methods to form a moisture barrier layer over an EUV-active photoresist film. The EUV-active photoresist film may be an improved EUV-active photoresist film as described further herein or a conventional metal oxide resist (MOR) film. The moisture barrier layer protects the EUV-active photoresist by preventing or reducing moisture and other contaminant uptake on the surface of the EUV-active photoresist film. In some embodiments, the moisture barrier layer may be transmissible to the light used in lithography processing, and thus, may remain on the surface of the EUV-active photoresist film during lithography processing.

Forming an EUV-Active Photoresist Film

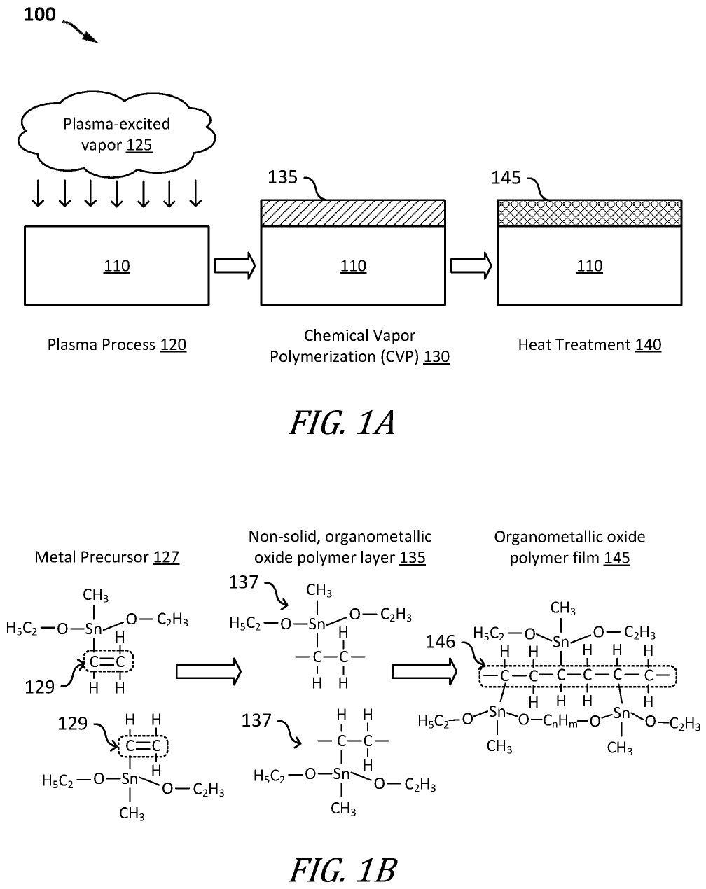

Turning now to the Drawings, FIG. 1A illustrates one embodiment of a process flow 100 that can be used to form an EUV-active photoresist film on a surface of a semiconductor substrate in accordance with one embodiment of the present disclosure. As shown in FIG. 1A, process flow 100 begins by performing a low temperature, low ion energy plasma process 120 that exposes the surface of the semiconductor substrate 110 to a plasma-excited vapor 125 containing a metal precursor having carbon-carbon double bonds. In some embodiments, an additive precursor may also be included within the plasma-excited vapor 125. Examples of suitable metal precursors and additive precursors are discussed in more detail below. During the plasma process 120, the semiconductor substrate 110 is maintained at a relatively low substrate temperature (for example, a substrate temperature less than about 100° C., and more preferably, less than about 0° C.), while ions within the plasma-excited vapor 125 are maintained at a relatively low ion energy (for example, an ion energy less than about 50 eV, and more preferably, between about 0 eV and about 5 eV). Under these conditions, a non-solid organometallic oxide polymer layer 135 is deposited onto the surface of the semiconductor substrate 110 via chemical vapor polymerization (CVP) 130.

Once the non-solid organometallic oxide polymer layer 135 is deposited onto the substrate surface, the semiconductor substrate 110 is subjected to a heat treatment 140 (for example, a thermal bake) to further polymerize the non-solid organometallic oxide polymer layer 135 and form an organometallic oxide polymer film 145 having carbon-carbon bonds on the substrate surface. The organometallic oxide polymer film 145 formed in accordance with the process flow 100 is an EUV-active photoresist film that can be patterned with EUV lithography and developed as described in more detail below.

As noted above, the plasma process 120 shown in FIG. 1A is performed at relatively low substrate temperatures and ion energies. According to one embodiment, the substrate temperature during the plasma exposure can, for example, be less than about 100° C. In other embodiments, the substrate temperature during the plasma exposure can be between about −50° C. and about 0° C., between about −50° C. and about −25° C., or between about −25° C. and about 0° C. According to one embodiment, the ion energy of the ions within the plasma-excited vapor 125 can be about 50 eV. In other embodiments, the ion energy can be less than 50 eV, for example, between about 0 eV and about 50 eV or between about 0 eV and about 5 eV. It is contemplated that the use of ion energy between about 0 eV and about 5 eV is beneficial to minimize plasma damage to the non-solid organometallic oxide polymer layer 135 deposited onto the substrate surface during the plasma process 120.

The plasma process 120 shown in FIG. 1A can be performed within a wide variety of plasma processing systems and/or chambers including, but not limited to, the following processing chambers. In some embodiments, the plasma process 120 may be performed within a capacitively coupled plasma (CCP) processing chamber or an inductively coupled plasma (ICP) processing chamber. In some examples, a CCP processing chamber having a source frequency of 13.56 MHz-60 MHz and a source power between about 10 W and about 500 W may be used to create plasma conditions that include an ion energy of about 50 eV (or less). A gas pressure within the CCP processing chamber can, for example, range between about 100 mTorr and about 20 Torr. The substrate temperature can be less than about 100° C., as set forth above.

In other embodiments, a plasma processing system containing a remote plasma source can be used to perform the plasma process 120 shown in FIG. 1A. Examples of such plasma processing systems include the use of remote plasma sources using radio frequency (RF), very high frequency (VHF), and microwave frequency (MWF). A plasma processing system containing a remote plasma source can include: (a) a vacuum chamber that is divided into a plasma space and a separate wafer space by a separation plate with plurality of holes, or (b) a plasma source that is attached to the vacuum chamber. A remote plasma source may be desirable in some embodiments, since it is effective in minimizing or eliminating exposure of the substrate to high energy ions.

The heat treatment 140 shown in FIG. 1A includes heat-treating the semiconductor substrate 110 containing the non-solid organometallic oxide polymer layer 135 formed thereon to further polymerize the non-solid organometallic oxide polymer layer 135 and form the organometallic oxide with polymerized carbon-carbon bonds. A wide variety of methods may be utilized to heat treat the semiconductor substrate 110. According to one embodiment, the heat treatment 140 step may be performed within a vacuum chamber at an elevated substrate temperature. In such embodiments, heat-treating may be performed under reduced pressure in the presence of an additive gas that can, for example, include hydrogen bromide (HBr), hydrogen (H₂), helium (He), argon (Ar), neon (Ne), xenon (Xe), nitrogen (N₂), and/or carbon monoxide (CO). In one example, the heat-treating may be performed using a substrate holder that acts as a hot-plate. Further, the heat-treating may be performed in the absence of plasma excitation or using plasma excitation of the additive gas. In another example, the heat-treating may be performed by optical means such as laser heating. According to one embodiment, the substrate temperature during the heat treatment 140 step can be between about 0° C. and about 400° C. In other embodiments, the substrate temperature during the heat treatment 140 step can be between about 0° C. and about 50° C., between about 50° C. and about 100° C., between about 100° C. and about 200° C., between about 200° C. and about 300° C., between about 0° C. and about 200° C., or between about 200° C. and about 400° C. Other methods for performing the polymerization shown in FIG. 1A can include, but are not limited to, using a hot filament above the substrate or using activation by e-beam, UV, EUV, High NA EUV, or Next Gen high NA/Hyper NA EUV.

A wide variety of metal precursors may be used during the plasma process 120 shown in FIG. 1A to form an EUV-active photoresist film. For example, a metal precursor comprising an EUV metal may be used. In the present disclosure, the term “EUV metal” may refer to a metal component with a high EUV absorption coefficient. According to one embodiment, the EUV metal may comprise tin (Sn). In other embodiments, the EUV metal may comprise zirconium (Zr), indium (In), antimony (Sb), bismuth (Bi), hafnium (Hf) or aluminum (Al). According to one embodiment, an organometallic oxide in the EUV-active photoresist film contains a central metal atom selected from the group consisting of tin (Sn), zirconium (Zr), indium (In), antimony (Sb), bismuth (Bi), zinc (Zn), hafnium (Hf), aluminum (Al) and combinations thereof. In the following description, various embodiments including figures are described using tin (Sn) as an exemplary metal component for the EUV-active photoresist film. It is recognized, however, that the metal component is not limited to tin (Sn) and other metals may also be present in the EUV-active photoresist film.

According to one embodiment, the metal precursor contains tin (Sn) and has the formula Sn_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. Examples include SnR1 (O—R2)₃, SnR1₂ (O—R2)₂, SnHR1(O—R2)₂, where R1: CH₃, C₂H₃, C₃H₅, C₄H₇, or C₆H₆, and R2: CH₃, C₂H₅, C₃H₇, or C₄H₉. Additional examples of a metal precursor containing tin (Sn) include SnCH₃^{t}Bu(O-^{t}BU)₂, Sn^{t}Bu(O-^{t}Bu)₃, Sn^{t}Bu(O—C₃H₇)₃, Sn^{t}Bu(O—C₂H₅)₃, Sn^{t}Bu(O—CH₃)₃, SnCH₃C₂H₃(O-^{t}Bu)₂, and SnCH₃(C₂H₃)(O—CH₃)₂, where Bu stands for butyl. Other examples of a metal precursor containing tin (Sn) include Sn(C₂H₄O₂) and Sn(OR)₂, where R may be selected from CH₃, C₂H₅ and C₄H₉. Still other examples include a mixture of Sn(N(CH₃)₂)₄ and HOCH₂CH₂OH.

According to another embodiment, the metal precursor contains tin (Sn) and has the formula SnₓC_{y}H_{z}, where x, y, and z are arbitrary integers of 1 or more. In one example, the metal precursor is selected from the group consisting of Sn(CH₃)₄, Sn(C₂H₅)₄, SnH(CH₃)₃, and SnH(C₂H₅)₃. In such an embodiment, the plasma-excited vapor 125 containing the metal precursor can further include an additive gas such as, but not limited to, hydrogen (H₂), helium (He), argon (Ar), neon (Ne), krypton (Kr), nitrogen (N₂) or acetylene (C₂H₂).

According to yet another embodiment, the metal precursor contains a transition metal (M) and has the formula M_{α}O_{β} (O—CₘHₙ)ΓCₓH_{y}, where m, n, and α are arbitrary integers of 1 or more, β, Γ, x, and y are arbitrary integers of 0 or more, and β and Γ are not 0 at the same time. Examples of transition metals having a high EUV absorption coefficient include, but are not limited to, tin (Sn), antimony (Sb), indium (In) and bismuth (Bi).

In some embodiments, the plasma-excited vapor 125 may include a metal precursor and an additive precursor. For example, when the metal precursor contains tin (Sn) and has the formula Sn_{α}O_{β} (O—CₘHₙ)ΓCₓH_{y}, the additive precursor added to the plasma-excited vapor 125 may contain tin (Sn) and have a formula Sn_{α}CₓH_{y}, where m, n, and a are arbitrary integers of 1 or more. When the metal precursor contains a transition metal (M) and has the formula M_{α}O_{β} (O—CₘHₙ)ΓCₓH_{y}, the additive precursor added to the plasma-excited vapor 125 may contain a transition metal (M) and have a formula MαCxHy, where m, n, and α are arbitrary integers of 1 or more.

According to one embodiment, the photo-sensitivity of the EUV-active photoresist film to EUV radiation may be amplified with an additive monomer by introducing species with carbon-oxygen double bonds (C═O) that surround the organometallic oxide. According to one embodiment, the plasma-excited vapor 125 can further contain an additive monomer, such as for example, a hydrocarbon containing C═O bonds. For example, the plasma-excited vapor 125 can further contain an additive monomer, such as a ketone, an aldehyde, or an ester, each of which contains a carbonyl group with a carbon-oxygen double bond (C═O). The ketone may be selected from the group consisting of acetone, methyl ethyl ketone, methyl propyl ketone, and methyl isopropyl ketone. The aldehyde may be selected from the group consisting of formaldehyde, acetaldehyde, and propionaldehyde. The ester may be selected from the group consisting of ethyl methanoate, methyl acetate, ethyl acetate, methyl acrylate, methyl butanoate, and methyl salicylate.

According to one embodiment, the plasma-excited vapor 125 can include a metal precursor containing tin (Sn) and the additive monomer can contain a ketone, an aldehyde, or an ester. According to one embodiment, the plasma-excited vapor 125 can further include an additive gas such as, but not limited to, hydrogen (H₂), helium (He), argon (Ar), neon (Ne), xenon (Xe), nitrogen (N₂), carbon monoxide (CO), ammonia (NH₃), or hydrogen sulfide (H₂S).

FIG. 1B illustrates example chemistry that can be utilized for the chemical vapor polymer deposition and heat treatment steps shown in FIG. 1A, including an example metal precursor 127 that can be used in the plasma process 120 to form an example non-solid, organometallic oxide polymer layer 135 on the surface of the semiconductor substrate 110. In FIG. 1B, the metal precursor 127 is an organic tin compound comprising a carbon-carbon double bond 129. The plasma excitation of the organic tin compound affects the carbon-carbon double bond 129 to form the non-solid organometallic oxide polymer layer 135 on the surface of the semiconductor substrate 110. The plasma-based reaction forms liquid-like oligomer units 137 of an organometallic oxide on the substrate surface. The subsequent heat treatment step further polymerizes the liquid-like oligomer units 137 of the non-solid organometallic oxide polymer layer 135 to form the organometallic oxide polymer film 145. As schematically shown in FIG. 1B, the liquid-like oligomer units 137 of the non-solid organometallic oxide polymer layer 135 polymerize, upon heat-treating, to form an EUV-active photoresist film comprising an organometallic oxide with a polymerized carbon-carbon backbone 146.

In the example embodiment shown in FIG. 1B, the EUV-active photoresist film is formed by plasma exciting SnCH₃(C₂H₃)(O—CH₃)₂ precursor molecules to form the non-solid organometallic oxide polymer layer 135 on the surface of the semiconductor substrate 110, followed by heat-treating the semiconductor substrate 110 to form the organometallic oxide polymer film 145 with polymerized carbon-carbon bonds.

In some embodiments, the plasma process 120 step shown in FIG. 1A may plasma-excite the SnCH₃(C₂H₃)(O—CH₃)₂ precursor molecules shown in FIG. 1B using a low temperature, low ion energy plasma process. During the plasma process 120, for example, the temperature of the semiconductor substrate 110 may be less than about 100° C. and the ion energy of the ions within the plasma-excited vapor 125 may be less than about 50 eV. In some embodiments, the SnCH₃(C₂H₃)(O—CH₃)₂ precursor molecules may be plasma-excited without the presence of an oxidizer such as, oxygen (O₂), ozone (O₃), water (H₂O), hydrogen peroxide (H₂O₂), carbon dioxide (CO₂) or carbon monoxide (CO). In some embodiments, the plasma excitation can include an additive gas, such as for example hydrogen (H₂), helium (He), argon (Ar), neon (Ne), krypton (Kr), nitrogen (N₂), acetylene (C₂H₂), or carbon monoxide (CO).

In some embodiments, the heat treatment 140 step shown in FIG. 1A may be performed within a vacuum chamber at an elevated substrate temperature, such as for example, between about 0° C. and about 400° C. In some embodiments, the heat treatment 140 step may be performed under reduced pressure in the presence of an additive gas that can, for example, include hydrogen bromide (HBr), hydrogen (H₂), helium (He), argon (Ar), neon (Ne), xenon (Xe), nitrogen (N₂), and/or carbon monoxide (CO).

The chemical vapor polymerization (CVP) shown in FIGS. 1A and 1B, namely the plasma excitation of the organic tin compound followed by heat-treating of the semiconductor substrate, forms an organometallic oxide with polymerized carbon-carbon bonds. As shown in FIG. 1B, the organic tin compound contains Sn—O— units that are protected by CₘHₙ ligands (for example, methane (CH₃) and ethyl radicals (C₂H₅)). The CₘHₙ ligands prevent Sn—O—Sn crosslinking (which creates weak and unstable bonds that increase film density and decrease EUV photosensitivity), and instead, provide stronger carbon-carbon bonding. Further, organic tin compounds containing carbon-carbon double bonds 129 enhance polymerization during the heat treatment 140 step to form an organometallic oxide polymer film 145 with a polymerized carbon-carbon backbone 146, which increases the mechanical strength and photo-sensitivity of the EUV-active photoresist film. In some embodiments, the photo-sensitivity of the EUV-active photoresist film may be further increased by adding a monomer to the plasma-excited vapor 125 (not shown in FIG. 1B), wherein the additive monomer has carbon-oxygen double bonds (C═O) that surround the organometallic oxide.

The EUV-active photoresist described above and shown in FIGS. 1A and 1B provides various advantages over conventional photoresists used for EUV lithography, such as chemically amplified resists (CARs) and vapor-deposited metal oxide-containing films. For example, the EUV-active photoresist disclosed herein has a higher EUV absorbance, and thereby better resist sensitivity, compared to conventional CARs. In some embodiments, the higher EUV absorbance may enable the thickness of the photoresist required for an acceptable performance to be decreased. The EUV-active photoresist disclosed herein may also exhibit an etch resistance that is better than conventional CARs. In addition, the methods disclosed above may enable a uniform chemical composition of the EUV-active photoresist, which may be beneficial in mitigating issues of blur or line edge roughness.

In addition to CARs, the EUV-active photoresist disclosed herein provides various advantages over conventional vapor-deposited metal oxide-containing films, such as those described in the '004 patent. Unlike the conventional processes disclosed in the '004 patent, which react various organotin oxide precursors with an oxidizer (for example, carbon dioxide or carbon monoxide) in a typical CVD/ALD process to form a solid metal oxide-containing film on the semiconductor substrate, the methods disclosed above use a low temperature, low ion energy plasma process, which exposes the substrate surface to a plasma-excited vapor comprising a metal precursor having carbon-carbon double bonds to deposit a non-solid, organometallic oxide polymer layer (containing liquid-like oligomer units) having carbon-carbon bonds onto the substrate surface. The carbon-carbon double bonds provided within the metal precursor enhance polymerization during the subsequently performed heat treatment step to form an organometallic oxide polymer film with carbon-carbon bonds. The presence of carbon-carbon bonds in the organometallic oxide polymer film increases the mechanical strength and stability of the EUV-active photoresist film disclosed herein compared to conventional vapor-deposited metal oxide-containing films containing Sn—OH and Sn—O—Sn bonds.

As noted above, many EUV-active photoresist films (including conventional metal oxide resist (MOR) films and the metal alkoxy polymer films described above and shown in FIGS. 1A and 1B) are chemically and mechanically fragile and tend to absorb moisture from the ambient environment. In the present disclosure, a moisture barrier is formed on an EUV-active photoresist film to prevent the EUV-active photoresist film from absorbing moisture from the ambient environment and chemically reacting with the moisture to form metal-oxide-metal species on the surface of the EUV-active photoresist film. The EUV-active photoresist film may be an EUV-active photoresist film, as described above and shown in FIGS. 1A-1B, or a conventional metal oxide resist (MOR) film.

Methods for Processing a Semiconductor Substrate

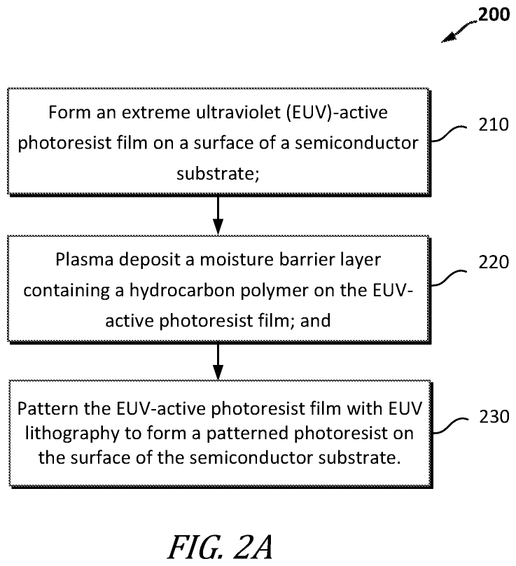

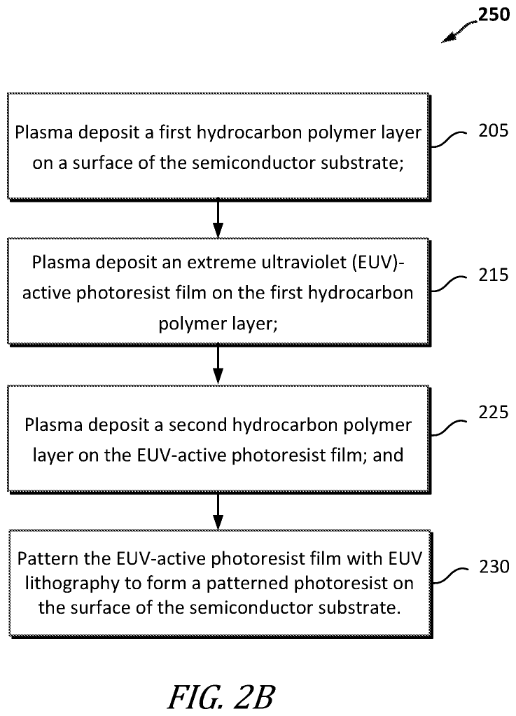

FIGS. 2A and 2B illustrate various embodiments of methods for processing a semiconductor substrate in accordance with the present disclosure. More specifically, FIGS. 2A and 2B illustrate methods that can be used to form a moisture barrier layer on an EUV-active photoresist film before patterning the EUV-active photoresist film with EUV lithography. It will be recognized that the embodiments shown in FIGS. 2A and 2B are merely exemplary and additional methods may utilize the techniques described herein. Further, additional processing steps may be added to the methods shown in the FIGS. 2A and 2B as the steps described are not intended to be exclusive. Moreover, the order of the steps is not limited to the order shown in the figures as different orders may occur and/or various steps may be performed in combination or at the same time.

FIG. 2A illustrates one embodiment of a method 200 in accordance with the present disclosure. According to one embodiment, the method 200 shown in FIG. 2A includes forming an EUV-active photoresist film on a surface of the semiconductor substrate (in step 210), plasma depositing a moisture barrier layer containing a hydrocarbon polymer on the EUV-active photoresist film (in step 220), and patterning the EUV-active photoresist film with EUV lithography to form a patterned photoresist on the surface of the semiconductor substrate (in step 230). Providing moisture barrier layer over the EUV-active photoresist film prevents the EUV-active photoresist film from reacting with the ambient environment and forming metal-oxide-metal species on the surface of the EUV-active photoresist film, which would degrade the material properties and quality of the EUV-active photoresist film during lithography processing.

FIG. 2B illustrates another embodiment of a method 250 in accordance with the present disclosure. According to one embodiment, the method 250 shown in FIG. 2B includes plasma depositing a first hydrocarbon polymer layer on a surface of the semiconductor substrate (in step 205) before plasma depositing the EUV-active photoresist film on the first hydrocarbon polymer layer (in step 215). After depositing the EUV-active photoresist film, the method 250 further includes plasma depositing a second hydrocarbon polymer layer on the EUV-active photoresist film (in step 225), and patterning the EUV-active photoresist film with EUV lithography to form a patterned photoresist on the surface of the semiconductor substrate (in step 230). Providing a first hydrocarbon polymer layer under the EUV-active photoresist film prevents the EUV-active photoresist film from reacting with the underlying silicon-containing substrate and forming metal-oxide-silicon species that are hard to remove during subsequent processing steps. In the embodiment shown in FIG. 2B, the second hydrocarbon polymer layer deposited on the EUV-active photoresist film in step 225 is a moisture barrier layer, as described above.

In some embodiments, the EUV-active photoresist film formed in steps 210 and 215 may be an organometallic oxide or metal oxide resist (MOR). In some embodiments, the EUV-active photoresist film formed in steps 210 and 215 may be an organometallic oxide with polymerized carbon-carbon bonds, as described above and shown in FIGS. 1A and/or 1B. In one example, the EUV-active photoresist film may be an organometallic oxide containing tin (Sn). In other examples, the EUV-active photoresist film may be an organometallic oxide containing zirconium (Zr), indium (In), antimony (Sb), bismuth (Bi), zinc (Zn), hafnium (Hf), aluminum (Al) or combinations thereof. In some embodiments, the EUV-active photoresist film may be formed in steps 210 and 215 by: (a) exposing the surface of the semiconductor substrate to a plasma-excited vapor comprising a metal precursor having carbon-carbon double bonds to form a non-solid organometallic oxide polymer layer on the surface of the semiconductor substrate, and (b) heat-treating the semiconductor substrate to further polymerize the non-solid organometallic oxide polymer layer and form the organometallic oxide with polymerized carbon-carbon bonds, as described above and shown in FIG. 1A. The EUV-active photoresist film formed in steps 210 and 215 may have a wide variety of thicknesses. For example, a thickness of the EUV-active photoresist film (e.g., an organometallic oxide with polymerized carbon-carbon bonds) can range between about 3 nm and about 5 nm, in some embodiments.

The first hydrocarbon polymer layer deposited in step 205 and the second hydrocarbon polymer layer (i.e., moisture barrier layer) deposited in steps 220 and 225 may contain a wide variety of hydrocarbon polymers. In some embodiments, the hydrocarbon polymer may include carbon and hydrogen. In example embodiments, the hydrocarbon polymer may include: a) carbon, hydrogen, and oxygen, b) carbon, hydrogen, oxygen, and nitrogen, or c) carbon, hydrogen, and nitrogen. The first and second hydrocarbon polymer layers may be formed in steps 205, 220 and 225 by plasma exciting a wide variety of precursors. For example, a hydrocarbon precursor, an aldehyde precursor and/or an amine precursor may be plasma exited to form one or more of the first and second hydrocarbon polymer layers. Examples of suitable precursors are discussed in more detail below.

The first hydrocarbon polymer layer deposited in step 205 and the second hydrocarbon polymer layer (i.e., moisture barrier layer) deposited in steps 220 and 225 can also be formed having a wide range of thicknesses. For example, the thickness of the moisture barrier layer deposited in step 220 and the second hydrocarbon polymer layer deposited in step 225 can be greater than 1 nm. When a first hydrocarbon polymer layer is utilized underneath the EUV-active photoresist film, the thickness of the first hydrocarbon polymer layer can also be greater than about 1 nm.

In some embodiments, a relatively thin (for example, about 1 nm to 10 nm) moisture barrier layer/second hydrocarbon polymer layer may be deposited in steps 220 and 225. In such embodiments, the EUV-active photoresist film may be patterned in step 230 by: (a) exposing the moisture barrier layer and the EUV-active photoresist film to EUV radiation, wherein regions of the EUV-active photoresist film exposed to the EUV radiation are converted to a reacted photoresist, while regions of the EUV-active photoresist not exposed to the EUV radiation remain unreacted; (b) removing the moisture barrier layer; and (c) removing certain regions of the EUV-active photoresist to form a photoresist pattern. In some embodiments, the patterning step may remove the unreacted regions of the EUV-active photoresist to form a first photoresist pattern (for example, a negative tone photoresist) on the substrate. In some embodiments, the method 200/250 may further include selectively depositing a material film on upper surfaces of the first photoresist pattern relative to the exposed surfaces of the semiconductor substrate. In some embodiments, the patterning step may remove the reacted regions of the EUV-active photoresist to form a second photoresist pattern (for example, a positive tone photoresist) on the substrate. In some embodiments, the method 200/250 may further include selectively depositing a material film on exposed surfaces of the semiconductor substrate relative to the second photoresist pattern.

In other embodiments, a relatively thick (for example, greater than 10 nm) moisture barrier layer/second hydrocarbon polymer layer may be deposited in steps 220 and 225. In such embodiments, the EUV-active photoresist film may be patterned in step 230 by: (a) exposing the moisture barrier layer to EUV radiation, wherein regions of the moisture barrier layer exposed to the EUV radiation are converted to a reacted moisture barrier layer and regions of the moisture barrier layer not exposed to the EUV radiation remain unreacted; (b) removing the regions of the reacted moisture barrier layer to form a patterned moisture barrier layer; and (c) exposing the EUV-active photoresist film to EUV radiation through openings in the patterned moisture barrier layer, wherein regions of the EUV-active photoresist film exposed to the EUV radiation are converted to a reacted photoresist and regions of the EUV-active photoresist not exposed to the EUV radiation remain unreacted. In some embodiments, the method 200/250 may further include selectively depositing a material film onto upper surfaces of the reacted photoresist and removing the patterned moisture barrier layer. The patterned moisture barrier layer may be removed before or after the material film is selectively deposited onto the upper surfaces of the reacted photoresist.

Forming a Film Structure Containing a Moisture Barrier Layer and an EUV-Active Photoresist Film

In the methods shown in FIGS. 2A and 2B, a moisture barrier layer is formed on an EUV-active photoresist film to prevent the EUV-active photoresist film from absorbing moisture from the ambient environment and chemically reacting with the moisture to form metal-oxide-metal species on the surface of the EUV-active photoresist film. When an organometallic oxide containing tin (Sn) is utilized as the EUV-active photoresist film, the moisture barrier layer prevents Sn—O—Sn species from forming on the surface of the EUV-active photoresist film. By protecting the EUV-active photoresist film from the ambient environment, the moisture barrier layer described herein increases the mechanical strength and stability of the EUV-active photoresist film.

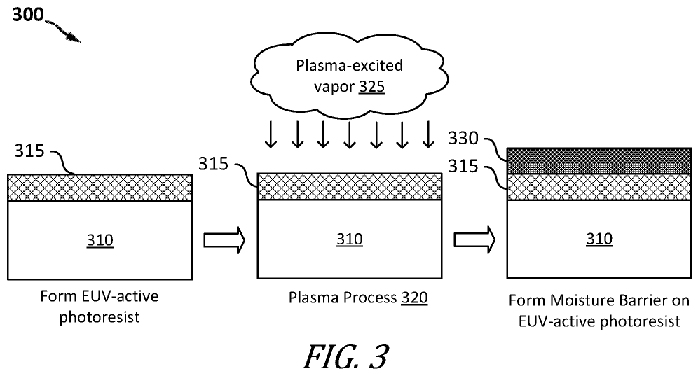

FIG. 3 illustrates one example of a process flow 300 that can be used to form a film structure comprising a moisture barrier layer 330 formed on an EUV-active photoresist film 315 according to one embodiment of the present disclosure. After forming an EUV-active photoresist film 315 on a surface of a semiconductor substrate 310, as shown for example in the process flow 100 of FIG. 1A, a moisture barrier layer 330 is deposited onto an upper surface of the EUV-active photoresist film 315 using plasma excitation of a precursor above the substrate surface. In some embodiments, the moisture barrier layer 330 may be plasma deposited onto the EUV-active photoresist film 315 by performing a plasma process 320, which exposes the surface of the EUV-active photoresist film 315 to a plasma-excited vapor 325 containing at least one precursor. A wide variety of precursors can be used to form the moisture barrier layer 330, as described in more detail below. By providing a film structure comprising moisture barrier layer 330 formed over an EUV-active photoresist film 315, the process flow 300 shown in FIG. 3 prevents the EUV-active photoresist film 315 from reacting with the ambient environment and forming undesirable form metal-oxide-metal species on the surface of the photoresist film.

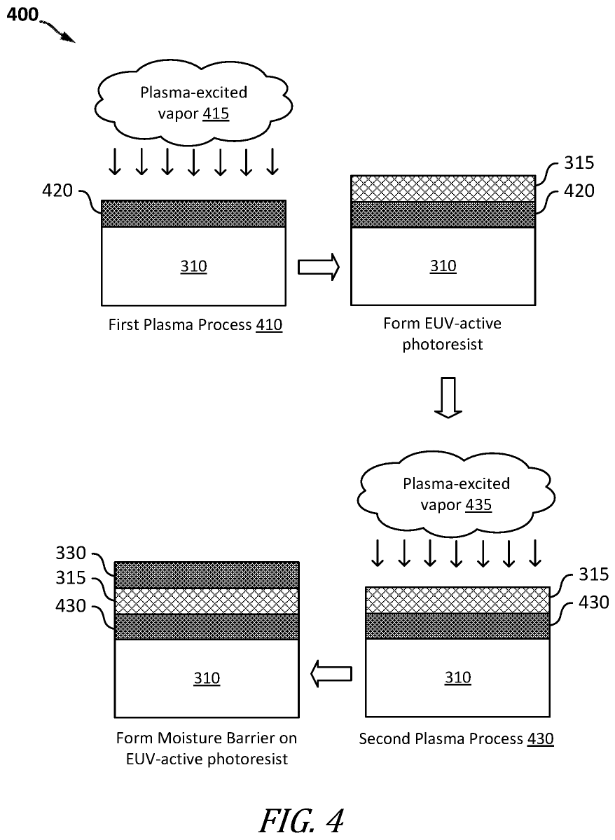

FIG. 4 illustrates another example of a process flow 400 that can be used to form a film structure comprising a moisture barrier layer 330 formed on an EUV-active photoresist film 315 according to another embodiment of the present disclosure. In the embodiment shown in FIG. 4, a first hydrocarbon polymer layer 420 is plasma deposited onto a surface of the semiconductor substrate 310 by performing a first plasma process 410, which exposes the surface of the semiconductor substrate 310 to a plasma-excited vapor 415 containing at least one precursor. Thereafter, an EUV-active photoresist film 315 is deposited onto the first hydrocarbon polymer layer 420 using, for example, the process flow 100 shown in FIG. 1A. After forming the EUV-active photoresist film 315, a moisture barrier layer 330 is deposited onto the EUV-active photoresist film 315 by performing a second plasma process 430, which exposes the surface of the EUV-active photoresist film 315 to a plasma-excited vapor 435 containing at least one precursor. In some embodiments, the moisture barrier layer 330 deposited onto the EUV-active photoresist film 315 may be a second hydrocarbon polymer layer, as described above. A wide variety of precursors may be used to form the first hydrocarbon polymer layer 420 and the moisture barrier layer 330 (e.g., the second hydrocarbon polymer layer), as described in more detail below.

In some embodiments, the semiconductor substrate 310 may be a silicon(Si)-containing substrate (e.g., SiC), and the first hydrocarbon polymer layer 420 can be deposited onto the substrate surface to reduce or prevent a chemical reaction between the EUV-active photoresist film 315 (e.g., a Sn-based photoresist) and the underlying Si-containing substrate. For example, a Sn-based photoresist may react with a Si-containing substrate to form Sn—O—Si species on the substrate surface that may be hard to remove during a subsequently performed developing step, which is performed to remove unreacted regions of the EUV-active photoresist film (i.e., regions of the EUV-active photoresist not exposed to EUV radiation during an EUV lithography step). By providing a film structure comprising a first hydrocarbon polymer layer 420 formed under an EUV-active photoresist film 315 and a second hydrocarbon polymer layer (e.g., moisture barrier layer 330) formed over the EUV-active photoresist film 315, the process flow 400 shown in FIG. 4 further prevents the EUV-active photoresist film 315 from reacting with the underlying substrate and forming undesirable form metal-oxide-silicon species on the surface of the substrate.

A wide variety of precursors may be utilized within the plasma process 320 shown in FIG. 3 and the first plasma process 410 and the second plasma process 430 shown in FIG. 4 to form a hydrocarbon polymer layer. In some embodiments, for example, a hydrocarbon precursor may be used to form the hydrocarbon polymer layer. The hydrocarbon precursor can have the formula C_{α}H_{β}, where α is an integer of 1 or more, and β is an arbitrary integer of 1 or more. Non-limiting examples of hydrocarbon precursors having the formula C_{α}H_{β} include, but are not limited to, a methyl radical (CH₃), acetylene (C₂H₂), ethylene (C₂H₄), a propyl radical (C₃H₇), and styrene (C₆H₅CH═CH₂). In some embodiments, the plasma excitation can further include an additive gas, such as for example, hydrogen (H₂), helium (He), argon (Ar), neon (Ne), xenon (Xe), nitrogen (N₂), carbon monoxide (CO), ammonia (NH₃) or hydrogen sulfide (H₂S).

Other examples of a precursor that may be used to form the hydrocarbon polymer layer can include an aldehyde precursor having the formula C_{α}H_{β}O_{γ}, where α is an integer of 1 or more, β is an arbitrary integer of 1 or more, and γ is an arbitrary integer of 1 or more. One example of an aldehyde precursor having the formula C_{α}H_{β}O_{γ} includes benzaldehyde (C₆H₅CHO). In some embodiments, the plasma excitation can further include an additive gas, for example hydrogen (H₂), helium (He), argon (Ar), neon (Ne), xenon (Xe), nitrogen (N₂), carbon monoxide (CO), ammonia (NH₃) or hydrogen sulfide (H₂S).

In yet other examples, an amine precursor may be used to form the hydrocarbon polymer layer, the amine precursor having the formula C_{α}H_{β}N_{γ}O_{δ}, where α is an integer of 1 or more, β is an arbitrary integer of 1 or more, γ is an arbitrary integer of 1 or more and δ is an integer of 0 or more. One example of an amine precursor having the formula C_{α}H_{β}N_{γ}O_{δ} includes phenylenediamine (C₆H₄(NH₂)₂). In some embodiments, the plasma excitation can further include an additive gas, for example hydrogen (H₂), helium (He), argon (Ar), neon (Ne), xenon (Xe), nitrogen (N₂), carbon monoxide (CO), ammonia (NH₃) or hydrogen sulfide (H₂S).

In the examples provided above, a hydrocarbon precursor, an aldehyde precursor and/or an amine precursor may be used to form the hydrocarbon polymer layer. In further examples, a mixture or combination of precursors can be used to form the hydrocarbon polymer layer. For example, the hydrocarbon polymer layer can be formed using a mixture of C_{α}H_{β}O_{γ} and C_{α}H_{β}N_{γ}O_{δ} precursors, as described above.

In some embodiments, the plasma process 320 shown in FIG. 3 and the first plasma process 410 and the second plasma process 430 shown in FIG. 4 may be performed at relatively low substrate temperatures and ion energies. According to one embodiment, the substrate temperature during the plasma-excitation of the precursor used to form the hydrocarbon polymer layer can, for example, be less than about 100° C. For example, the substrate temperature during the plasma exposure can be between about −50° C. and about 0° C., between about −50° C. and about −25° C., or between about −25° C. and about 0° C. According to one embodiment, the ion energy of the ions within the plasma-excited vapor 325, the plasma-excited vapor 415 and/or the plasma-excited vapor 435 can be about 50 eV. In other embodiments, the ion energy can be less than 50 eV, for example, between about 0 eV and about 50 eV or between about 0 eV and about 5 eV.

A wide variety of plasma processing systems and/or chambers can be utilized to perform the plasma process 320 shown in FIG. 3 and the first plasma process 410 and the second plasma process 430 shown in FIG. 4 including, but not limited to, the following processing chambers. In some embodiments, one or more of the plasma processes 320, 410 and 430 may be performed within a capacitively coupled plasma (CCP) processing chamber or an inductively coupled plasma (ICP) processing chamber. In some examples, a CCP processing chamber having a source frequency of 13.56 MHz-60 MHz and a source power between about 10 W and about 500 W may be used to create plasma conditions that include an ion energy of about 50 eV (or less). A gas pressure within the CCP processing chamber can, for example, be between about 100 mTorr and about 20 Torr. The substrate temperature can be less than about 100° C., as set forth above.

In other embodiments, a plasma processing system containing a remote plasma source can be utilized to perform one or more of the plasma processes 320, 410 and 430. Examples of such plasma processing systems include the use of remote plasma sources using radio frequency (RF), very high frequency (VHF), and microwave frequency (MWF). A plasma processing system containing a remote plasma source can include: (a) a vacuum chamber that is divided into a plasma space and a separate wafer space by a separation plate with plurality of holes, or (b) a plasma source that is attached to the vacuum chamber. A remote plasma source may be desirable in some embodiments, since it is effective in minimizing or eliminating exposure of the substrate to high energy ions.

Patterning a Film Structure Containing a Moisture Barrier Layer and an EUV-Active Photoresist Film

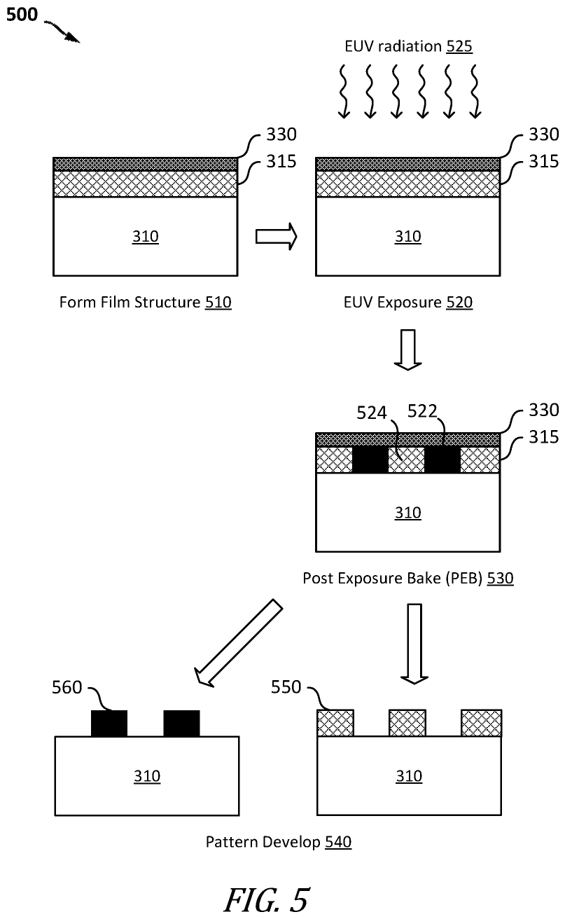

FIG. 5 illustrates an example process flow 500 that can be used to pattern a film structure containing a moisture barrier layer formed on an EUV-active photoresist film. Although process flow 500 is shown patterning the film structure shown in FIG. 3, the patterning process described herein is not strictly limited to the film structure shown in FIG. 3 and may be applied to other film structures, such as for example, the film structure shown in FIG. 4.

In some embodiments, process flow 500 may begin by forming a film structure 510 containing an EUV-active photoresist film 315 formed on a semiconductor substrate 310 and a moisture barrier layer 330 formed on the EUV-active photoresist film 315, as described above and shown in FIG. 3. In the embodiment shown in FIG. 5, the film structure 510 includes a relatively thin moisture barrier layer 330 having, for example, a thickness less than about 10 nm. The relatively thin moisture barrier layer 330 formed above the EUV-active photoresist film 315 is at least partially transparent to EUV radiation. This enables EUV radiation to pass through the moisture barrier layer 330 and reach the EUV-active photoresist film 315 during the EUV lithography process, which is subsequently performed to pattern the EUV-active photoresist film 315.

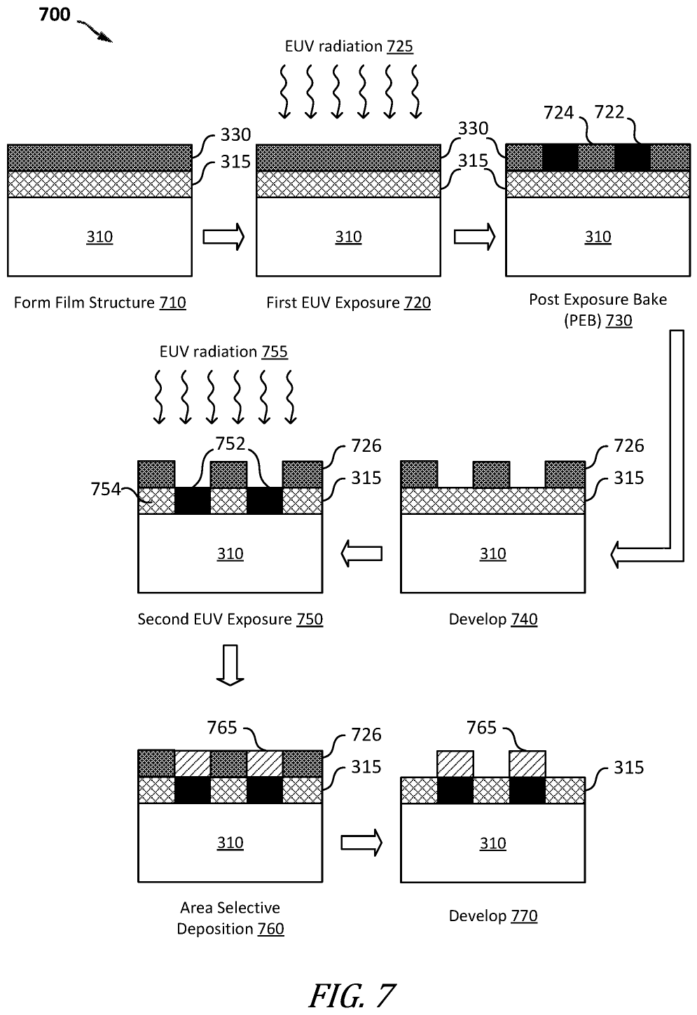

In other embodiments (not shown in FIG. 5), the moisture barrier layer 330 can be thick enough to absorb all or most of the EUV radiation, resulting in little or no EUV radiation reaching the EUV-active photoresist film 315 during a subsequently performed EUV lithography process. In such embodiments, a first EUV lithography process may be performed to pattern the moisture barrier layer 330 before a second EUV lithography process is performed to pattern portions of the EUV-active photoresist film 315 underlying the moisture barrier layer pattern, as shown for example in FIG. 7.

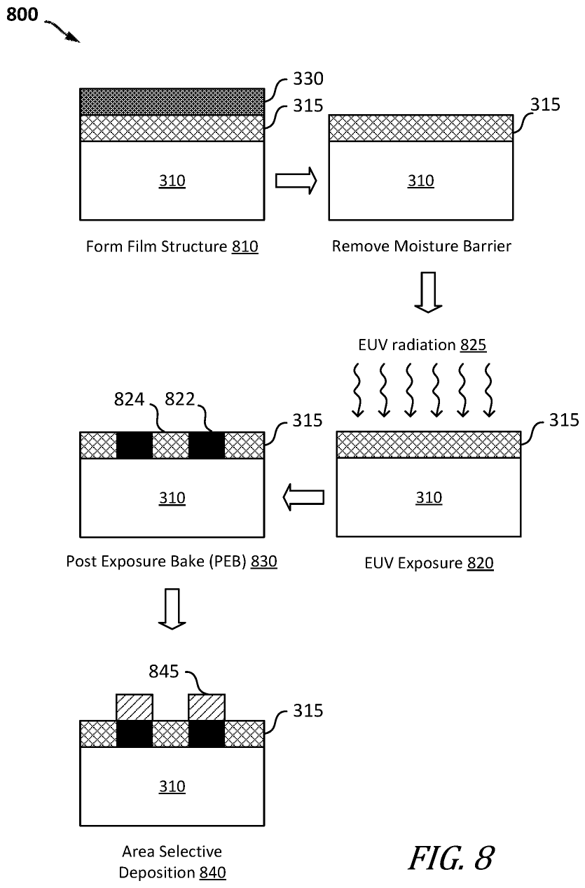

After forming the film structure 510 containing the moisture barrier layer 330 and the EUV-active photoresist film 315, the process flow 500 shown in FIG. 5 performs an EUV lithography process, which exposes the film structure 510 to EUV radiation 525 (e.g., at a wavelength of 13.5 nm) in an EUV exposure 520 step. In other embodiments (not shown in FIG. 5), the moisture barrier layer 330 may be removed prior to exposure to the EUV radiation, as shown for example in FIG. 8. The EUV lithography process may utilize a photomask (not shown in FIG. 5) such that a photo-induced reaction occurs only in the regions 522 of the EUV-active photoresist film 315 exposed to the EUV radiation 525. The regions 522 of the EUV-active photoresist film 315 exposed to the EUV radiation 525 are converted to a reacted photoresist. Regions 524 of the EUV-active photoresist film 315 not exposed to the EUV radiation 525 remain unreacted. After the EUV exposure 520 step, an optional heat-treating step (for example, post-exposure bake (PEB)) 530 may be performed to stabilize the photoresist after EUV exposure by completing the reactions initiated during exposure. In some embodiments, the optional heat-treating step 530 may prevent changes in line edge roughness (LER), line width roughness (LWR) and/or critical dimension (CD).

After completing the EUV exposure 520 and optional post-exposure bake (PEB) 530, a developing step 540 may be performed to remove the moisture barrier layer 330 and a portion of the EUV-active photoresist film for patterning, thereby providing a patterned photoresist (or photoresist pattern) on the substrate surface. The developing step 540 may be a wet or dry process. In some embodiments, a wet process may be used in the developing step 540. For example, a portion of the EUV-active photoresist may be removed by treating the substrate with a developing solution to: (a) dissolve the reacted regions 522 of the EUV-active photoresist film 315 resulting in a positive tone photoresist 550, or (b) dissolve the unreacted regions 524 of the EUV-active photoresist film 315 resulting in a negative tone photoresist 560. Alternately, a dry process may be used to remove the reacted or unreacted regions of the EUV-active photoresist in other embodiments. The dry process may comprise, for example, a selective plasma etch process or a thermal process, advantageously eliminating the use of a developing solution. In certain embodiments, the dry process may be performed using a reactive ion etching (RIE) process or atomic layer etching (ALE).

Area Selective Deposition on Patterned Photoresists

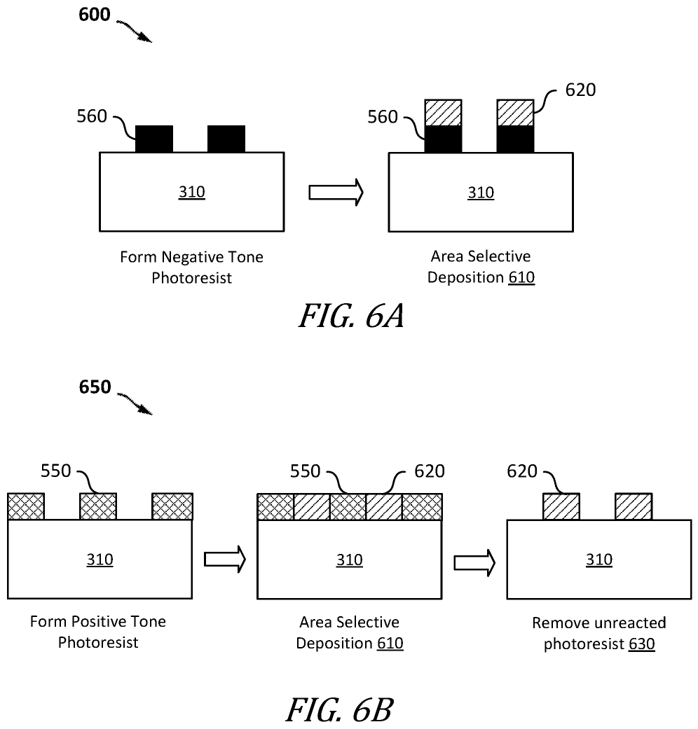

In some embodiments, one or more of the pattern photoresists formed in FIG. 5 may be utilized for Area Selective Deposition (ASD) of a material film. FIG. 6A illustrates one example of a process flow 600 that can be used for selective film deposition of a material film on a photoresist pattern containing a reacted photoresist (or negative tone photoresist 560). After forming a negative tone photoresist 560 as shown in FIG. 5, the process flow 600 shown in FIG. 6A utilizes Area Selective Deposition (ASD) 610 to preferentially deposit a material film 620 onto upper surfaces of the reacted photoresist relative to the exposed surfaces of the semiconductor substrate 310. In other embodiments (not shown in FIG. 6A), selective deposition can alternatively be achieved by using an inhibition layer on the reacted photoresist and depositing the material film on exposed surfaces of the underlying semiconductor substrate 310.

FIG. 6B illustrates one example of a process flow 650 that can be used for selective film deposition on a photoresist pattern containing an unreacted photoresist (or positive tone photoresist 550). After forming the positive tone photoresist 550 as shown in FIG. 5, the process flow 650 shown in FIG. 6B utilizes Area Selective Deposition (ASD) 610 to preferentially deposit a material film 620 onto exposed surfaces of the semiconductor substrate 310 relative to the upper surfaces of the unreacted photoresist. Thereafter, the unreacted photoresist is removed from the semiconductor substrate 310, leaving the deposited material film 620 on the substrate surface.

FIG. 7 illustrates another example of a process flow 700 that can be used to perform Area Selective Deposition (ASD) using a patterned photoresist in accordance with a second embodiment of the present disclosure. Although process flow 700 is shown patterning the film structure shown in FIG. 3, the process described herein is not strictly limited to the film structure shown in FIG. 3 and may be applied to other film structures, such as for example, the film structure shown in FIG. 4.

In some embodiments, process flow 700 may begin by forming a film structure 710 containing an EUV-active photoresist film 315 formed on a semiconductor substrate 310 and a moisture barrier layer 330 formed on the EUV-active photoresist film 315, as described above and shown in FIG. 3. In the embodiment shown in FIG. 7, the film structure 710 includes a relatively thick moisture barrier layer 330 having, for example, a thickness greater than about 10 nm. The moisture barrier layer 330 can be thick enough to absorb all or most of the EUV radiation, resulting in little or no EUV radiation reaching the EUV-active photoresist film 315 during a subsequently performed EUV lithography process.

After forming the film structure 710 containing the moisture barrier layer 330 and the EUV-active photoresist film 315, the process flow 700 shown in FIG. 7 performs an EUV lithography process, which exposes the film structure 710 to EUV radiation 725 (e.g., at a wavelength of 13.5 nm) in a first EUV exposure 720 step. In this embodiment, the moisture barrier layer 330 formed above the EUV-active photoresist film 315 is thick enough and/or chemically tailored to absorb all or most of the EUV radiation 725, resulting in little or no EUV radiation reaching the EUV-active photoresist film 315. The EUV lithography process may utilize a photomask (not shown in FIG. 7) such that a photo-induced reaction occurs only in regions 722 of the moisture barrier layer 330 that are exposed to the EUV radiation 725. The regions 722 of the moisture barrier layer 330 exposed to the EUV radiation 725 are converted to a reacted moisture barrier layer. Regions 724 of the moisture barrier layer 330 not exposed to the EUV radiation 725 remain unreacted. After the first EUV exposure 720 step, an optional heat-treating step (for example, post-exposure bake (PEB)) 730 may be performed to stabilize the reacted moisture barrier layer after EUV exposure by completing the reactions initiated during exposure.

After completing the first EUV exposure 720 and an optional post-exposure bake (PEB) 730, a developing step 740 may be performed to remove a portion of moisture barrier layer for patterning. The developing step 740 may be a wet or dry process. The resulting pattern includes either the reacted or unreacted moisture barrier layer, and exposes a portion of the underlying EUV-active photoresist film 315. In some embodiments, a wet process may be used in the developing step 740. For example, a portion of the moisture barrier layer may be removed by treating the substrate with a developing solution to: (a) dissolve the reacted regions 722 of the moisture barrier layer 330, or (b) dissolve the unreacted regions 724 of the moisture barrier layer 330, to form a moisture barrier layer pattern. FIG. 7 shows an embodiment where the resulting moisture barrier layer pattern 726 includes unreacted regions 724 of the moisture barrier layer 330. Alternately, a dry process may be used remove the reacted or unreacted regions of the moisture barrier layer in other embodiments. The dry process may comprise, for example, a selective plasma etch process or a thermal process, advantageously eliminating the use of a developing solution. In certain embodiments, the dry process may be performing using reactive ion etching (RIE) process or atomic layer etching (ALE).

Next, the process flow 700 shown in FIG. 7 may expose the film structure 710 to EUV radiation 755 (e.g., at a wavelength of 13.5 nm) in a second EUV exposure 750 step. The second EUV lithography process exposes the EUV-active photoresist film 315 to EUV radiation 755 through openings in the moisture barrier layer pattern 726. In the second EUV exposure 750 step, only the regions 752 of the EUV-active photoresist film 315, which are exposed by the moisture barrier layer pattern 726, are exposed to the EUV radiation 755 and converted to a reacted photoresist. Regions 754 of the EUV-active photoresist film 315 not exposed to the EUV radiation 755 remain unreacted.

After the EUV-active photoresist film 315 is patterned to form a reacted photoresist, the process flow 700 shown in FIG. 7 utilizes Area Selective Deposition (ASD) 760 to preferentially deposit a material film 765 onto upper surfaces of the reacted photoresist relative to the moisture barrier layer pattern 726. Thereafter, a developing step 770 may be performed to remove the moisture barrier layer pattern 726 from the substrate, leaving the deposited material film 765 on the substrate. In other embodiments (not shown in FIG. 7), the moisture barrier layer pattern 726 may be removed prior to Area Selective Deposition (ASD) 760 of the material film 765.

FIG. 8 illustrates yet another example of a process flow 800 that can be used to perform Area Selective Deposition (ASD) using a patterned photoresist in accordance with a third embodiment of the present disclosure. Like the previous embodiments, the film structure shown in FIG. 3 is depicted in the process flow 800. Like the previous embodiments, the process flow 800 is not strictly limited to the film structure shown in FIG. 3 and may be applied to other film structures such as, for example, the film structure shown in FIG. 4.

In some embodiments, process flow 800 may begin by forming a film structure 810 containing an EUV-active photoresist film 315 formed on a semiconductor substrate 310 and a moisture barrier layer 330 formed on the EUV-active photoresist film 315, as described above and shown in FIG. 3. Unlike the previous embodiments, the moisture barrier layer 330 is removed prior to EUV exposure in the embodiment shown in FIG. 8.

After the moisture barrier layer 330 is removed, the process flow 800 shown in FIG. 8 performs an EUV lithography process, which exposes the EUV-active photoresist film 315 to EUV radiation 825 (e.g., at a wavelength of 13.5 nm) in an EUV exposure 820 step. The EUV lithography process may utilize a photomask (not shown in FIG. 8) such that a photo-induced reaction occurs only in regions 822 of the EUV-active photoresist film 315 that are exposed to the EUV radiation 825. The regions 822 of the EUV-active photoresist film 315 exposed to the EUV radiation 825 are converted to a reacted photoresist. Regions 824 of the EUV-active photoresist film 315 not exposed to the EUV radiation 825 remain unreacted. After the EUV exposure 820 step, an optional heat-treating step (for example, post-exposure bake (PEB)) 830 may be performed to stabilize the reacted photoresist after EUV exposure by completing the reactions initiated during exposure. After the EUV-active photoresist film 315 is patterned to form a reacted photoresist, the process flow 800 shown in FIG. 8 utilizes Area Selective Deposition (ASD) 840 to preferentially deposit a material film 845 onto upper surfaces of the reacted photoresist relative to the unreacted photoresist.

A wide variety of material films may be selectively deposited in the process flows shown in FIGS. 6A, 6B, 7 and 8. In some embodiments, a dielectric material such as, for example, a silicon oxide (SiO), silicon nitride (SiN), titanium oxide (TiO), zirconium oxide (ZrO), hafnium oxide (HfO), etc., may be selectively deposited in one or more of the process flows shown in FIGS. 6A, 6B, 7 and 8. In other embodiments, a metal material such as, for example, a titanium nitride (TiN), ruthenium (Ru), etc., may be selectively deposited in the process flows described above.

The present disclosure provides various embodiments of improved process flows and methods for forming an EUV-active photoresist film, comprising an organometallic oxide polymerized with carbon-carbon bonds, for use in EUV photolithographic processes. The process flows and methods disclosed herein improve upon conventional methods of forming EUV-active photoresists by utilizing chemical vapor polymerization (CVP) to deposit metal oxide resist complexes on the substrate surface using a low temperature, low ion energy plasma process. The low temperature, low ion energy plasma process uses a variety of metal precursors having carbon-carbon double bounds to form liquid-like oligomer units on the substrate surface which further polymerize upon heat treatment to form new organometallic compounds with improved mechanical strength and stability compared to conventional EUV-active photoresists. Using the process flows and methods disclosed herein, the new organometallic compounds are formed with excellent uniformity and better nucleation on the underlying surfaces (even hydrophobic surfaces). The process flows and methods disclosed herein also provide faster deposition on hydrophobic surfaces by using CVP to deposit liquid-like oligomer units on the substrate surface, instead of depositing a rigid metal oxide film using traditional CVD or ALD. Although the new organometallic compounds described herein can be deposited at a wide variety of thicknesses (for example, less than 10 nm up to several hundred nm), the process flows and methods disclosed herein may enable a thinner, more uniform photoresist coating to be deposited onto the substrate surface, which in turn, can be used to transfer sub-10 nm features to underlying layers of the substrate.

In addition, the present disclosure provides various embodiments of improved process flows and methods for protecting an EUV-active photoresist film by providing a hydrocarbon polymer layer above and/or below the EUV-active photoresist film. The hydrocarbon polymer layer formed above the EUV-active photoresist film serves as a moisture control/barrier layer, which prevents the EUV-active photoresist film from chemically reacting with moisture in the ambient environment and forming undesirable metal-oxide-metal species on the surface of the photoresist. The hydrocarbon polymer layer formed below the EUV-active photoresist film prevents the EUV-active photoresist film from chemically reacting with the underlying silicon substrate and forming undesirable metal-oxide-silicon species on the substrate surface. As such, the hydrocarbon polymer layers described herein improve performance of an EUV-active photoresist film by preventing unwanted reactions on upper/lower surfaces of the photoresist.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of processing a semiconductor substrate, the method comprising:
forming an extreme ultraviolet (EUV)-active photoresist film on a surface of the semiconductor substrate;
plasma depositing a moisture barrier layer containing a hydrocarbon polymer on the EUV-active photoresist film; and
patterning the EUV-active photoresist film with EUV lithography to form a patterned photoresist on the surface of the semiconductor substrate.

2. The method of claim 1, wherein the hydrocarbon polymer comprises carbon and hydrogen.

3. The method of claim 1, wherein the hydrocarbon polymer comprises: a) carbon, hydrogen, and oxygen, b) carbon, hydrogen, oxygen, and nitrogen, or c) carbon, hydrogen, and nitrogen.

4. The method of claim 1, wherein said plasma depositing the moisture barrier layer comprises plasma exciting a hydrocarbon precursor having a formula of C_{α}H_{β}, where α is an integer of 1 or more, and β is an integer of 1 or more.

5. The method of claim 4, wherein the hydrocarbon precursor includes CH₃, C₂H₂, C₂H₄, C₃H₇, or C₆H₅CH═CH₂.

6. The method of claim 1, wherein said plasma depositing the moisture barrier layer comprises plasma exciting an aldehyde precursor having a formula of C_{α}H_{β}O_{γ}, where α is an integer of 1 or more, β is an integer of 1 or more, and γ is an integer of 1 or more.

7. The method of claim 1, wherein said plasma depositing the moisture barrier layer comprises plasma exciting an amine precursor having a formula of C_{α}H_{β}N_{γ}O_{δ}, where α is an integer of 1 or more, β is an integer of 1 or more, γ is an integer of 1 or more and δ is an integer of 0 or more.

8. The method of claim 1, wherein said plasma depositing the moisture barrier layer is performed within a capacitively coupled plasma (CCP) processing chamber having a source frequency of 13.56 MHz-60 MHz, a source power between about 10 W and about 500 W, an ion energy of about 50 eV or less, a gas pressure between about 100 mTorr and about 20 Torr, and a substrate temperature less than about 100° C.

9. The method of claim 1, wherein the EUV-active photoresist film is an organometallic oxide containing tin (Sn), zirconium (Zr), indium (In), antimony (Sb), bismuth (Bi), hafnium (Hf) or aluminum (Al).

10. The method of claim 1, wherein said patterning the EUV-active photoresist film comprises:
exposing the moisture barrier layer and the EUV-active photoresist film to EUV radiation, wherein reacted regions of the EUV-active photoresist film exposed to the EUV radiation are converted to a reacted photoresist, and wherein unreacted regions of the EUV-active photoresist not exposed to the EUV radiation remain unreacted;
removing the moisture barrier layer; and
removing the unreacted regions of the EUV-active photoresist to form a first photoresist pattern or removing the reacted regions of the EUV-active photoresist to form a second photoresist pattern on the semiconductor substrate.

11. The method of claim 10, further comprising:
selectively depositing a material film on upper surfaces of the first photoresist pattern relative to exposed surfaces of the semiconductor substrate.

12. The method of claim 10, further comprising:
selectively depositing a material film on exposed surfaces of the semiconductor substrate relative to the second photoresist pattern.

13. The method of claim 1, wherein said patterning the EUV-active photoresist comprises:
exposing the moisture barrier layer to EUV radiation, wherein first regions of the moisture barrier layer exposed to the EUV radiation are converted to a reacted moisture barrier layer and second regions of the moisture barrier layer not exposed to the EUV radiation remain unreacted;
removing the first regions of the moisture barrier layer converted to the reacted moisture barrier layer to form a patterned moisture barrier layer; and
exposing the EUV-active photoresist film to EUV radiation through openings in the patterned moisture barrier layer, wherein reacted regions of the EUV-active photoresist film exposed to the EUV radiation are converted to a reacted photoresist, and wherein unreacted regions of the EUV-active photoresist not exposed to the EUV radiation remain unreacted.

14. The method of claim 13, further comprising:
selectively depositing a material film on upper surfaces of the reacted photoresist.

15. The method of claim 13, further comprising:
removing the patterned moisture barrier layer.

16. A method of processing a semiconductor substrate, the method comprising:
plasma depositing a first hydrocarbon polymer layer on a surface of the semiconductor substrate;
plasma depositing an extreme ultraviolet (EUV)-active photoresist film on the first hydrocarbon polymer layer;
plasma depositing a second hydrocarbon polymer layer on the EUV-active photoresist film; and
patterning the EUV-active photoresist film with EUV lithography to form a patterned photoresist on the surface of the semiconductor substrate.

17. The method of claim 16, wherein the first hydrocarbon polymer layer and the second hydrocarbon polymer layer each comprise carbon and hydrogen.

18. The method of claim 16, wherein the first hydrocarbon polymer layer and the second hydrocarbon polymer layer each comprise: a) carbon, hydrogen, and oxygen, b) carbon, hydrogen, oxygen, and nitrogen, or c) carbon, hydrogen, and nitrogen.

19. The method of claim 16, wherein at least one of said plasma depositing the first hydrocarbon layer and said plasma depositing the second hydrocarbon layer comprises:
plasma exciting a hydrocarbon precursor having a formula of C_{α}H_{β}, where α is an integer of 1 or more, and β is an integer of 1 or more.

20. The method of claim 19, wherein the hydrocarbon precursor includes CH₃, C₂H₂, C₂H₄, C₃H₇, or C₆H₅CH═CH₂.

21. The method of claim 16, wherein at least one of said plasma depositing the first hydrocarbon layer and said plasma depositing the second hydrocarbon layer comprises:
plasma exciting an aldehyde precursor having a formula of C_{α}H_{β}O_{γ}, where α is an integer of 1 or more, β is an integer of 1 or more, and γ is an integer of 1 or more.

22. The method of claim 16, wherein at least one of said plasma depositing the first hydrocarbon layer and said plasma depositing the second hydrocarbon layer comprises:
plasma exciting an amine precursor having a formula of C_{α}H_{β}N_{γ}O_{δ}, where α is an integer of 1 or more, β is an integer of 1 or more, γ is an integer of 1 or more and δ is an integer of 0 or more.

23. The method of claim 16, wherein the EUV-active photoresist film is an organometallic oxide containing tin (Sn), zirconium (Zr), indium (In), antimony (Sb), bismuth (Bi), hafnium (Hf) or aluminum (Al).
